(19) United States
(12) Patent Application Publication
(10) Pub. No.: US 2011/0250527 A1
(43) Pub. Date: Oct. 13, 2011

(54) MASK LAYOUT

(76) Inventor: HONGTAO LI, Singapore (SG)

(21) Appl. No.: 12/758,786

(22) Filed: Apr. 12, 2010

(51) Int. Cl. G03F 1/00

(52) U.S. Cl. 430/5

(57) ABSTRACT

A mask layout is disclosed. The mask layout includes a mask body, a mask pattern disposed on a surface of the mask body, and a cover disposed on the mask body. Preferably, the mask body and the cover include a medium therebetween and the cover includes no filter.

### BACKGROUND OF THE INVENTION

1. Field of the Invention

The invention relates to a mask layout, and more particularly, to a mask layout capable of enduring distortion from air blow of nitrogen gun.

2. Description of the Prior Art

Generally, semiconductor devices are used in a variety of electronic applications, such as computers, cellular phones, personal computing devices, and many other applications. Home, industrial, and automotive devices that in the past comprised only mechanical components now have electronic parts that require semiconductor devices, for example.

Semiconductor devices are manufactured by depositing many different types of material layers over a semiconductor workpiece or wafer, and patterning the various material layers using lithography. The material layers typically comprise thin films of conductive, semiconductive, and insulating materials that are patterned and etched to form integrated circuits (ICs). There may be a plurality of transistors, memory devices, switches, conductive lines, diodes, capacitors, logic circuits, and other electronic components formed on a single die or chip, for example.

Optical photolithography involves projecting or transmitting light through a pattern comprised of optically opaque or translucent areas and optically clear or transparent areas on a mask or reticle. For many years in the semiconductor industry, optical lithography techniques such as contact printing, proximity printing, and projection printing have been used to pattern material layers of integrated circuits. Lens projection systems and transmission lithography masks are used for patterning, wherein light is passed through the lithography mask to impinge upon a photosensitive material layer disposed on semiconductor wafer or workpiece. After development, the photosensitive material layer is then used as a mask to pattern an underlying material layer.

There is a trend in the semiconductor industry towards scaling down the size of integrated circuits, to meet the demands of increased performance and smaller device size. As features of semiconductor devices become smaller, it becomes more difficult to pattern the various material layers because of diffraction and other effects that occur during the lithography process. In particular, mask layout used in lithography techniques for patterning the various material layers become challenging as device features shrink.

In conventional mask layout design, a mask pattern is formed on the surface of a mask body, and a thin membrane is disposed on the mask body for protecting the mask pattern from fallen particles during the course of the fabrication. Typically, as particles fall onto the thin membrane, nitrogen guns are used to blow off particles from the surface of the thin membrane. However, due to their less desirable thickness, conventional thin membranes are often vulnerable from outside disturbances and a blowing action from nitrogen gun often results in rupture of the entire membrane.

Hence, a filter is usually installed on a region of the thin membrane to filter out unwanted particles. Despite most particles are isolated from the membrane through the utilization of a filter, chemicals such as ammonium gas could still penetrate through the filter and disrupt the mask pattern. It is therefore desirable to come up with a mask layout for improving the drawback of conventional mask design.

### SUMMARY OF THE INVENTION

It is an objective of the present invention to provide a mask layout for solving the aforementioned issue met by conventional mask design.

According to a preferred embodiment of the present invention, a mask layout is disclosed. The mask layout includes a mask body, a mask pattern disposed on a surface of the mask body, and a cover disposed on the mask body. Preferably, the mask body and the cover includes a medium therebetween and the cover includes no filter.

According to another aspect of the present invention, a mask layout is disclosed. The mask layout includes a mask body, a mask pattern disposed on a surface of the mask body, and a cover mounted on the mask body. Preferably, the cover is sealed along the surface of the mask body and the mask pattern and the cover comprises no filter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a perspective view of a mask layout according to a preferred embodiment of the present invention.

FIG. 2 illustrates a perspective view of a mask layout according to an embodiment of the present invention.

### DETAILED DESCRIPTION

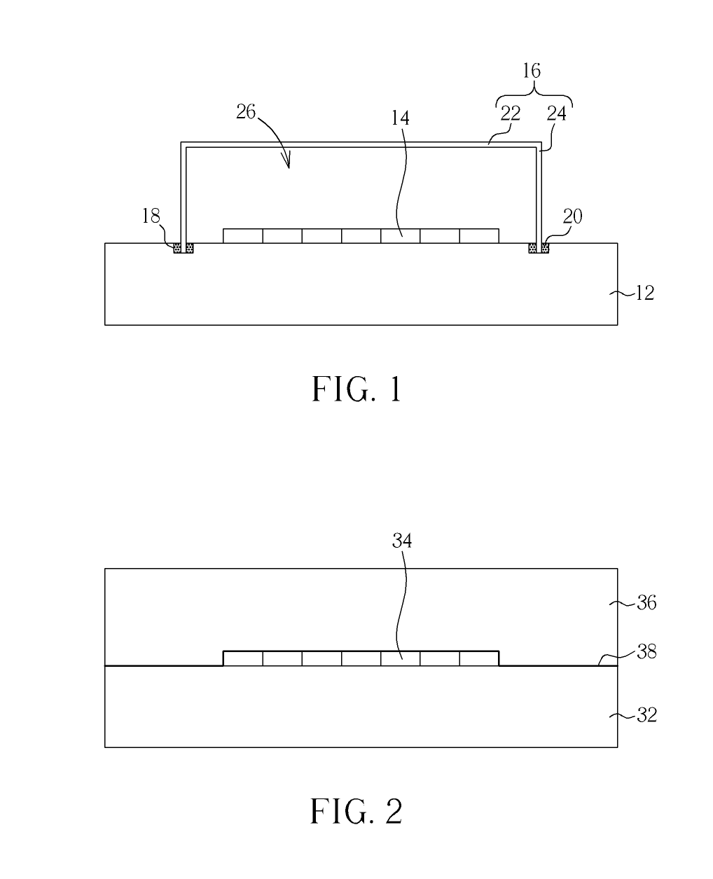

Referring to FIG. 1, FIG. 1 illustrates a perspective view of a mask layout according to a preferred embodiment of the present invention. As shown in FIG. 1, the mask layout includes a mask body 12, a mask pattern 14 disposed on the surface of the mask body 12, and a cover 16 mounted on the mask body 12. The mask body 12 is preferably composed of transparent materials such as glass or quartz, and the mask pattern 14 is preferably made of opaque material such as chromium for shielding the exposure light. In the exposure process, the exposure light not blocked by the mask pattern 14 preferably passes through to a lens to be focused on a wafer.

In this embodiment, a chamfer 18 could be formed on the top surface of the mask body 12 to surround the mask pattern 14, and a cover adhesive 20 could be deposited in the chamfer 18 to adhere the cover 16 onto the mask body 12. Preferably, the cover 16 is composed of transparent material to allow exposure light to pass freely, the width of the chamfer 18 is controlled below 0.05 μm and the adhesive 20 is deposited to fill the chamfer 18 entirely.

The cover 16 in this embodiment is preferably a ∩-shaped structure having a top 22 and two sidewalls 24 inserted into the chamfer 18. As the cover 16 is only disposed on a portion of the mask body 12 without contacting the surface of the mask pattern 14, medium such as air 26 is included between the cover 16 and the mask pattern 14.

Despite only one adhesive 20 is applied in this embodiment for adhering the cover 18 onto the mask body 12, an additional adhesive (not shown) could be applied selectively to the tip surface of the sidewalls 24 of the cover 16 being inserted into the chamfer 18. In other words, a first adhesive could be applied on the tip portion of the sidewalls 24 and a second adhesive could be deposited in the chamfer 18 before the two elements are united, in which the first adhesive and the second adhesive could be same or different. By applying two separate adhesives onto the tip portion of the sidewalls 24 of the cover 16 and into the chamfer 18, the adhesion between the two elements is strengthened substantially.

Also, it should be noted that despite a chamfer 18 is formed in this embodiment for accommodating the cover 16, the cover 16 could also be mounted directly on the surface of the mask body 12 without the formation of a chamfer 18, which is also within the scope of the present invention. Hence, the tip portion of the cover 18 could be applied with an adhesive and then mounted directly on the surface of the mask body 12.

As shown in FIG. 1, the cover 16 is disposed around the mask pattern 14 without contacting any part of the mask pattern 14. According to a preferred embodiment of the present invention, the thickness of the cover 16 is less than 0.005 μm, and the optical transmission of the cover 16 is greater than 99% for an exposure light projecting at 193 nm or 248 nm. The longevity of the cover 16 is preferably at 100 KJ/cm2 for more than 98% transmission storage and using without organic vapor; and 500 KJ/cm2 for more than 98% transmission storage and using without organic vapor.

By adhering the aforementioned cover 16 onto the mask body 12, the present invention could use the cover 16 as a protective shield to stop particles as well as chemical gases from contacting the mask pattern 14. Moreover, as the cover 16 is composed of thick and transparent material, the mask layout design prevents the cover 16 from breaking or rupture as nitrogen guns were used to blow off particles from the surface of the cover 16 while eliminating the usage of a filter, and also allows exposure light to pass through the portion not shielded by the mask pattern freely.

Referring to FIG. 2, FIG. 2 illustrates a perspective view of a mask layout according to an embodiment of the present invention. As shown in FIG. 2, the mask layout includes a mask body 32, a mask pattern 34 disposed on the surface of the mask body 32, and a cover 36 mounted on the mask body 32. The mask body 32 is preferably composed of transparent materials such as glass or quartz, and the mask pattern 34 is preferably made of opaque material such as chromium for shielding the exposure light. The cover 36 in this embodiment is preferably composed of transparent material such as glass, in which the glass used for the cover could be the same material or different material as used in the mask body 32.

In this embodiment, the cover 36 is preferably mounted on the mask body 32 through an adhesive 38 while the bottom surface of the cover 36 is sealed along the surface of the mask body 32 and the mask pattern 34. In other words, the bottom surface of the cover 36 is adhered to the top surface of the mask body 32 and the surface of the mask pattern 34 while the adhesive 38 is disposed between the cover 36, the mask body 32, and the mask pattern 34. In addition to applying the adhesive 38 between the cover 36, the mask body 32, and the mask pattern 34 as revealed in this embodiment, the adhesive 38 could also be applied only between the contacting surface of the cover 36 and the mask body 32, which is also within the scope of the present invention.

As the cover 36 is tightly adhered onto the surface of the mask body 32 and the mask pattern 34, the unification and bonding between the cover 34, the mask pattern 34 and the mask body 32 is ensured as no air medium is presented between these elements.

Moreover, as the cover 36 is preferably composed of solid and transparent material such as glass, this embodiment also prevents the cover 36 from breaking as well as scratches as nitrogen guns were used to blow off particles from the surface of the cover 16 while eliminating the usage of a filter.

Those skilled in the art will readily observe that numerous modifications and alterations of the device and method may be made while retaining the teachings of the invention.

What is claimed is:

1. A mask layout, comprising:
a mask body;
a mask pattern disposed on a surface of the mask body;
a cover disposed on the mask body, wherein the mask body and the cover comprises a medium therebetween and the cover comprises no filter.

2. The mask layout of claim 1, wherein the mask body comprises glass or quartz.

3. The mask layout of claim 1, where the cover comprises a transparent cover.

4. The mask layout of claim 1, wherein the medium comprises air.

5. The mask layout of claim 1, wherein the mask pattern comprises chromium.

6. The mask layout of claim 1, wherein the mask body comprises at least a chamfer surrounding the mask pattern for accommodating the cover.

7. The mask layout of claim 6, further comprising an adhesive disposed in the chamfer for adhering the mask body and the cover.

8. The mask layout of claim 1, wherein the thickness of the cover is less than 0.005 μm.

9. The mask layout of claim 1, wherein the optical transmission of the cover is less than 99% at 193 nm or 248 nm.

10. A mask layout, comprising:
a mask body;
a mask pattern disposed on a surface of the mask body;
a cover mounted on the mask body, wherein the cover is sealed along the surface of the mask body and the mask pattern and the cover comprises no filter.

11. The mask layout of claim 10, wherein the mask body comprises glass or quartz.

12. The mask layout of claim 10, wherein the cover comprises a transparent cover.

13. The mask layout of claim 12, wherein the transparent cover comprises glass.

14. The mask layout of claim 10, wherein the mask pattern comprises chromium.

15. The mask layout of claim 10, further comprising an adhesive adhered between the cover, the mask body, and the mask pattern.
